(19) United States
(12) Patent Application Publication
(10) Pub. No.: US 2026/0164686 A1
(43) Pub. Date: Jun. 11, 2026

(54) TUNNEL CURRENT DRIVEN ELEMENT

(71) Applicant: NATIONAL INSTITUTE OF ADVANCED INDUSTRIAL SCIENCE AND TECHNOLOGY, Tokyo (JP)

(72) Inventors: Kimihiko Kato, Ibaraki (JP); Takahiro Mori, Ibaraki (JP); Shota IIzuka, Ibaraki (JP); Takashi Nakayama, Chiba (JP); Sanghun Cho, Chiba (JP)

(21) Appl. No.: 18/836,327

(22) PCT Filed: Jan. 13, 2023
(86) PCT No.: PCT/JP2023/000736

§ 371 Date: Aug. 6, 2024

(30) Foreign Application Priority Data
Feb. 10, 2022 (JP) 2022-019819

(51) Int. Cl. H10D 8/75; H10D 48/36

(52) U.S. Cl. CPC H10D 8/755; H10D 48/362

(57) ABSTRACT

A large ON-state current is obtained through use of an indirect transition semiconductor and variations in electrical characteristics between elements are suppressed. A tunneling current driven element (10) includes a first conductivity type semiconductor layer (1), a second conductivity type semiconductor layer (2) and an intermediate layer in which, in a direction directed from the first conductivity type semiconductor layer (1) toward the second conductivity type semiconductor layer (2), a first base material layer (3a), a quantum well layer (4) and a second base material layer (3b) are laminated in the stated order. The first base material layer (3a) is formed of a first semiconductor material, the second base material layer (3b) is formed of a second semiconductor material, and the quantum well layer (4) is formed of a third semiconductor material of a type different from the first semiconductor material and the second semiconductor material. The third semiconductor material has at least one of a band structure in which a valence band edge is present at an energy position higher than valence band edges of the first semiconductor material and the second semiconductor material and a band structure in which a conduction band edge is present at an energy position lower than conduction band edges of the first semiconductor material and the second semiconductor material.

### TECHNICAL FIELD

The present invention relates to a tunneling current driven element for achieving element drive by a tunneling current caused by a band-to-band tunneling phenomenon.

### BACKGROUND ART

There have been known a tunneling diode and a tunneling field effect transistor as tunneling current driven elements. Those elements achieve element drive by a tunneling current caused by a band-to-band tunneling phenomenon.

However, those elements have a problem in that a tunneling current (ON-state current) at the time of drive is small.

Incidentally, there are two types of semiconductor materials for manufacturing the tunneling current driven element, that is, a direct transition semiconductor and an indirect transition semiconductor. The former mainly corresponds to a compound semiconductor, and the latter mainly corresponds to a group IV semiconductor.

The probability at which the band-to-band tunneling phenomenon occurs is generally higher in the direct transition semiconductor than in the indirect transition semiconductor, and hence it is considered that usage of the compound semiconductor is effective in increasing the ON-state current (see Non Patent Document 1).

However, the technique of utilizing the compound semiconductor cannot use many of existing semiconductor element manufacturing facilities for manufacture of the tunneling current driven element. Thus, new capital investment is required, and there arises a problem of an increase in manufacturing cost.

Meanwhile, typical materials of the group IV semiconductor are silicon and germanium. Although the tunneling current driven element can be manufactured through use of existing semiconductor element manufacturing facilities, the probability at which the band-to-band tunneling phenomenon occurs is low, and there still remains challenges towards the increase of the ON-state current.

That is, in an energy band structure of the indirect transition semiconductor, the momentum at a valence band top and the momentum at a conduction band bottom do not match each other, and there is a deviation in momentum between electrons at the valence band top and electrons at the conduction band bottom.

In state transition of electrons from the valence band to the conduction band along with the band-to-band tunneling, the law of conservation of momentum is required to be satisfied. In the tunneling current driven element using the indirect transition semiconductor having a deviation in momentum, it is difficult to obtain the large tunneling current due to this restriction of the law of conservation of momentum.

In order to address this problem, the inventors of the present invention have reported the tunneling current driven element in which the ON-state current is increased by introducing isoelectronic trap (IET) forming impurities into the indirect transition semiconductor (see Patent Document 1).

FIG. 1(a) shows a configuration example of a tunneling diode using the IET forming impurities.

A tunneling diode 100 according to this example has a structure in which an intrinsic semiconductor layer 103 is arranged between an N⁺ semiconductor layer 101 and a P⁺ semiconductor layer 102, and is formed by introducing the IET forming impurities.

When a reverse direction voltage is applied to this tunneling diode 100, as illustrated in FIG. 1(b), electrons can tunnel from the valence band to the conduction band through use of an IET level formed in a bandgap as a bridge, and thus the probability at which the band-to-band tunneling phenomenon occurs can be increased. FIG. 1(b) is a view for illustrating a band structure in the tunneling diode using the IET forming impurities.

However, the IET forming impurities introduced in the tunneling diode 100 are introduced by ion implantation into the N⁺ semiconductor layer 101, the P⁺ semiconductor layer 102 and the intrinsic semiconductor layer 103, and are thus randomly distributed. Thus, as illustrated in FIG. 1(a), introduction positions of the IET forming impurities cannot be controlled, and the IET levels are formed randomly at a plurality of positions with variations as illustrated in FIG. 1(b).

As a result, the tunneling diode 100 has a problem in that variations in electrical characteristics are liable to be caused in each manufacture.

### PRIOR ART DOCUMENT

### Patent Document

Patent Document 1: JP 6253034 B2

### Non Patent Document

Non Patent Document 1: M. P.-Ladriere et al., Nature Physics 4, 776 (2008)

### DISCLOSURE OF THE INVENTION

### Problems to be Solved by the Invention

A problem to be solved by the present invention is to solve the various problems in the related art to achieve the following object. That is, a problem to be solved by the present invention is to provide a tunneling current driven element with which a large ON-state current can be obtained through use of an indirect transition semiconductor and variations in electrical characteristics between elements can be suppressed.

### Means for Solving the Problems

A solution to the above-mentioned problem is specifically as described below.

<1> A tunneling current driven element, including: a first conductivity type semiconductor layer formed of an indirect transition semiconductor material, the first conductivity type semiconductor layer having a first conductivity type which is a conductivity type of at least one selected from the group consisting of a “p” type and an “n” type and having an impurity concentration of 3×10¹⁹ cm⁻³ or more; a second conductivity type semiconductor layer formed of the indirect transition semiconductor material, the second conductivity type semiconductor layer having a second conductivity type which is a conductivity type different from the first conductivity type; and an intermediate layer arranged so as to be sandwiched between the first conductivity type semiconductor layer and the second conductivity type semiconductor layer, the intermediate layer being formed of at least one selected from the group consisting of an intrinsic semiconductor and an impurity-containing semiconductor having an impurity concentration lower than impurity concentrations of the first conductivity type semiconductor layer and the second conductivity type semiconductor layer, wherein the intermediate layer is a layer having a laminate structure in which, assuming a first direction directed from the first conductivity type semiconductor layer toward the second conductivity type semiconductor layer as a laminating direction, on the first conductivity type semiconductor layer serving as a base layer, at least one first base material layer and at least one quantum well layer are alternately laminated in the stated order, and a second base material layer is laminated on the at least one quantum well layer on a side closest to the second conductivity type semiconductor layer, wherein the at least one first base material layer is a layer that is formed of a first semiconductor material selected from the indirect transition semiconductor material and has a thickness in the first direction of from 0.5 nm to 20 nm, wherein the second base material layer is a layer that is formed of a second semiconductor material selected from the indirect transition semiconductor material and has a thickness in the first direction of from 10 nm to 500 nm, and wherein the at least one quantum well layer is a layer that is formed of a third semiconductor material selected from the indirect transition semiconductor material of a type different from the first semiconductor material and the second semiconductor material and has a thickness in the first direction of from 0.5 nm to 10 nm, the third semiconductor material being selected from the indirect transition semiconductor material having a band structure of at least one selected from the group consisting of a first band structure and a second band structure, the first band structure having a valence band edge present at an energy position higher than valence band edges of the first semiconductor material and the second semiconductor material, the second band structure having a conduction band edge present at an energy position lower than conduction band edges of the first semiconductor material and the second semiconductor material.
<2> The tunneling current driven element according to the above-mentioned item <1>, wherein the band structure is at least one selected from the group consisting of a first band structure and a second band structure, the first band structure having the valence band edge present at an energy position higher by more than 0.1 eV than a valence band edge having a highest energy position out of the first semiconductor material and the second semiconductor material, the second band structure having the conduction band edge present at an energy position lower by more than 0.1 eV than a conduction band edge having a lowest energy position out of the first semiconductor material and the second semiconductor material.
<3> The tunneling current driven element according to the above-mentioned item <1> or <2>, wherein the first semiconductor material, the second semiconductor material and the third semiconductor material are at least one selected from the group consisting of the following combinations (1) to (6):
(1) a combination in which the first semiconductor material and the second semiconductor material are Si and the third semiconductor material is Si₁₋ₓGeₓ, where “x” exceeds 0 and is less than 1;
(2) a combination in which the first semiconductor material and the second semiconductor material are Si and the third semiconductor material is Ge;
(3) a combination in which the first semiconductor material and the second semiconductor material are Si₁₋ₓGeₓ, where “x” exceeds 0 and is less than 1, and the third semiconductor material is Si_{1-y}Ge_{y}, where “y” is a value exceeding 0 and being less than 1 and further being larger than “x”;
(4) a combination in which the first semiconductor material and the second semiconductor material are Si₁₋ₓGeₓ, where “x” exceeds 0 and is less than 1, and the third semiconductor material is Ge;
(5) a combination in which the first semiconductor material and the second semiconductor material are Si and the third semiconductor material is Si₁₋ₓCₓ, where “x” exceeds 0 and is less than 1; and
(6) a combination in which the first semiconductor material and the second semiconductor material are Si and the third semiconductor material is Si_{1-x-y}GeₓC_{y}, where “x” exceeds 0 and is less than 1, “y” exceeds 0 and is less than 1, and “x+y” is less than 1.
   <4> The tunneling current driven element according to the above-mentioned item <3>, wherein the first semiconductor material, the second semiconductor material and the third semiconductor material are the combination (1), and “x” is 0.12 or more.
   <5> The tunneling current driven element according to any one of the above-mentioned items <1> to <4>, wherein the first conductivity type semiconductor layer, the second conductivity type semiconductor layer and the intermediate layer are each formed as a single crystal layer of the indirect transition semiconductor material.
   <6> The tunneling current driven element according to any one of the above-mentioned items <1> to <5>, wherein the thickness of the at least one first base material layer in the first direction is 8 nm or less.
   <7> The tunneling current driven element according to any one of the above-mentioned items <1> to <6>, further including an element structure of a tunneling diode in which, between an n-type semiconductor layer and a p-type semiconductor layer, a low impurity concentration layer is arranged, the low impurity concentration layer being formed of at least one selected from the group consisting of an intrinsic semiconductor and an impurity-containing semiconductor having an impurity concentration lower than impurity concentrations of the n-type semiconductor layer and the p-type semiconductor layer, wherein the element structure includes at least one selected from the group consisting of a first element structure and a second element structure, the first element structure including: the n-type semiconductor layer formed of a first conductivity type semiconductor layer having a first conductivity type being an “n” type; the p-type semiconductor layer formed of a second conductivity type semiconductor layer having a second conductivity type being a “p” type; and the low impurity concentration layer formed of an intermediate layer, the second element structure including: the p-type semiconductor layer formed of the first conductivity type semiconductor layer having the first conductivity type being the “p” type; the n-type semiconductor layer formed of the second conductivity type semiconductor layer having the second conductivity type being the “n” type; and the low impurity concentration layer formed of the intermediate layer.
   <8> The tunneling current driven element according to any one of the above-mentioned items <1> to <6>, further including an element structure of a tunneling field effect transistor in which a channel region is formed between a source region and a drain region and a gate electrode is formed above the channel region through intermediation of a gate insulating film, wherein the source region is formed of the first conductivity type semiconductor layer, the drain region is formed of the second conductivity type semiconductor layer, and the channel region is formed of the intermediate layer.
   <9> The tunneling current driven element according to the above-mentioned item <8>, wherein a length of the at least one quantum well layer in a second direction orthogonal to the first direction as viewed from a position in contact with the gate insulating film is at least 5 nm.

### Advantageous Effects of the Invention

According to the present invention, it is possible to solve the various problems in the related art. That is, it is possible to provide a tunneling current driven element with which a large ON-state current can be obtained through use of an indirect transition semiconductor and variations in electrical characteristics between elements can be suppressed.

### BRIEF DESCRIPTION OF THE DRAWINGS

FIG. 1(a) is a view for illustrating a configuration example of a tunneling diode using IET forming impurities.

FIG. 1(b) is a view for illustrating a band structure in an ON state of the tunneling diode using the IET forming impurities.

FIG. 2(a) is a cross-sectional explanatory view for illustrating a tunneling current driven element according to one embodiment of the present invention.

FIG. 2(b) is a view for illustrating a band structure in an ON state of the tunneling current driven element according to the present invention.

FIG. 3 is a table for showing band structures in general heterojunctions.

FIG. 4 is an explanatory view for illustrating a relationship between a tunneling window and a quantum well.

FIG. 5 is a cross-sectional explanatory view for illustrating a modification example of the tunneling current driven element 10.

FIG. 6(a) is a view (1) for illustrating a band structure example in an ON state of the tunneling current driven element according to the modification example.

FIG. 6(b) is a view (2) for illustrating a band structure example in the ON state of the tunneling current driven element according to the modification example.

FIG. 7(a) is a cross-sectional explanatory view for illustrating a configuration example of a practical tunneling current driven element in a case of being applied as a tunneling diode.

FIG. 7(b) is a schematic cross-sectional view (1) for illustrating an outline of a process of manufacturing a tunneling current driven element 20.

FIG. 7(c) is a schematic cross-sectional view (2) for illustrating the outline of the process of manufacturing the tunneling current driven element 20.

FIG. 7(d) is a schematic cross-sectional view (3) for illustrating the outline of the process of manufacturing the tunneling current driven element 20.

FIG. 7(e) is a schematic cross-sectional view (4) for illustrating the outline of the process of manufacturing the tunneling current driven element 20.

FIG. 8 is a cross-sectional explanatory view for illustrating a tunneling current driven element in a case of being applied to a tunneling field effect transistor.

FIG. 9(a) is an explanatory band structure view (1) for illustrating an operation of an N-type tunneling field effect transistor.

FIG. 9(b) is an explanatory band structure view (2) for illustrating the operation of the N-type tunneling field effect transistor.

FIG. 10(a) is an explanatory band structure view (1) for illustrating an operation of a P-type tunneling field effect transistor.

FIG. 10(b) is an explanatory band structure view (2) for illustrating the operation of the P-type tunneling field effect transistor.

FIG. 11(a) is a cross-sectional explanatory view for illustrating a practical configuration example of a practical tunneling current driven element in a case of being applied to a tunneling field effect transistor.

FIG. 11(b) is a schematic cross-sectional explanatory view (1) for illustrating an outline of a process of manufacturing a tunneling current driven element 40.

FIG. 11(c) is a schematic cross-sectional explanatory view (2) for illustrating the outline of the process of manufacturing the tunneling current driven element 40.

FIG. 11(d) is a schematic cross-sectional explanatory view (3) for illustrating the outline of the process of manufacturing the tunneling current driven element 40.

FIG. 11(e) is a schematic cross-sectional explanatory view (4) for illustrating the outline of the process of manufacturing the tunneling current driven element 40.

FIG. 11(f) is a schematic cross-sectional explanatory view (5) for illustrating the outline of the process of manufacturing the tunneling current driven element 40.

FIG. 12 is a cross-sectional explanatory view for illustrating a modification example of the tunneling current driven element 30.

FIG. 13 is a view for illustrating a test target model of a simulation test.

FIG. 14 is an explanatory view for illustrating a setting state of a distance (x₀) between an N⁺-type Si semiconductor layer and a center position of a SiGe quantum well layer in a first direction.

FIG. 15 is a graph for showing an energy band structure of each of Si and SiGe (Ge composition of 60%) obtained through the simulation test.

FIG. 16 is a graph for showing characteristics of tunneling currents of a PIN-type tunneling diode in the simulation test.

FIG. 17(a) is a view for illustrating a positional relationship between a tunneling window and a quantum well obtained by a SiGe quantum well layer in a model having x₀ of 5.6 nm.

FIG. 17(b) is a view for illustrating a positional relationship between the tunneling window and the quantum well obtained by the SiGe quantum well layer in a model having x₀ of 8.8 nm.

FIG. 18 is an explanatory view for illustrating a configuration of a tunneling current driven element according to Example.

FIG. 19 is a view for illustrating a carrier (electron or hole) density distribution in a tunneling current driven element according to Comparative Example.

FIG. 20 is a view for illustrating a TEM image of a laminate structure part of an intermediate layer (i-Si/i-SiGe/i-Si) of the tunneling current driven element according to Example.

FIG. 21 is a graph for showing results obtained by measuring I-V characteristics of the respective tunneling current driven elements according to Example and Comparative Example.

### MODE FOR CARRYING OUT THE INVENTION

### (Tunneling Current Driven Element)

A tunneling current driven element of the present invention is described with reference to the drawings.

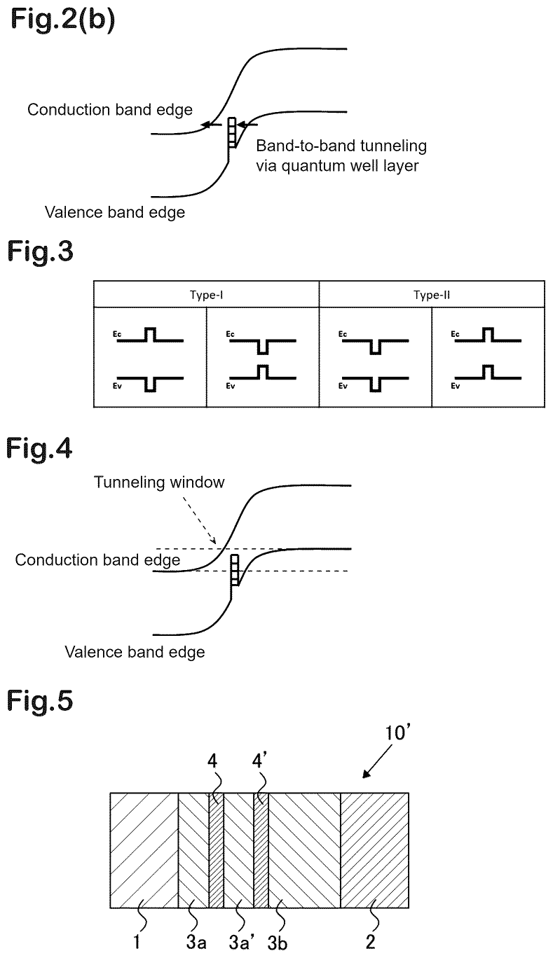

FIG. 2(a) shows a tunneling current driven element according to one embodiment of the present invention.

As illustrated in FIG. 2(a), a tunneling current driven element 10 includes a first conductivity type semiconductor layer 1, a second conductivity type semiconductor layer 2 and an intermediate layer. The intermediate layer includes a first base material layer 3a, a quantum well layer 4 and a second base material layer 3b.

The “tunneling current driven element” as used herein means a semiconductor element to be driven through use of a tunneling current that is based on a band-to-band tunneling phenomenon caused in the element, and corresponds to tunneling diodes such as an Esaki diode and a resonant tunneling diode, tunneling field effect transistors and the like.

### <First Conductivity Type Semiconductor Layer>

The first conductivity type semiconductor layer 1 is formed of an indirect transition semiconductor material, has a first conductivity type which is a conductivity type of a “p” type or an “n” type, and has an impurity concentration of 3×10¹⁹ cm⁻³ or more.

The indirect transition semiconductor material is not particularly limited and can be selected as appropriate depending on the purpose. Examples of the indirect transition semiconductor material include various forming materials of a semiconductor layer including impurities at a high concentration in a publicly-known tunneling diode, and various forming materials of a semiconductor layer configured as a source region and a drain region in a publicly-known tunneling field effect transistor.

Silicon (Si) is given as a preferred typical example of the indirect transition semiconductor material because the tunneling current driven element can be easily manufactured through use of many of existing semiconductor element manufacturing facilities.

The impurity concentration of the first conductivity type semiconductor layer 1 is only required to be 3×10¹⁹ cm⁻³ or more, but the impurity concentration is preferred to be as high as possible, with an upper limit of about 3×10²⁰ cm⁻³.

The impurities that determine the conductivity type are not particularly limited and can be selected as appropriate depending on the purpose. Examples of the impurities include impurities used in manufacture of a publicly-known semiconductor element. Boron (B) can be typically given in the case of p-type impurities, and phosphorus (P) can be typically given in the case of n-type impurities.

A method of forming the first conductivity type semiconductor layer 1 is not particularly limited and can be selected as appropriate depending on the purpose. Examples of the method include various methods of forming a semiconductor layer including impurities at a high concentration in a publicly-known tunneling diode, and various methods of forming a semiconductor layer configured as a source region and a drain region in a publicly-known tunneling field effect transistor.

An epitaxial growth method is given as a preferred forming method from the viewpoint of suppressing variations in electrical characteristics through use of a high-quality semiconductor layer. The epitaxial growth method uses a semiconductor layer having crystal orientation as a template.

Further, the first conductivity type semiconductor layer 1 may be formed as a single crystal layer, a polycrystalline layer or an amorphous layer of the indirect transition semiconductor material, but is preferred to be formed as a single crystal layer of the indirect transition semiconductor material from the viewpoint of suppressing variations in electrical characteristics through use of a high-quality semiconductor layer.

### <Second Conductivity Type Semiconductor Layer>

The second conductivity type semiconductor layer 2 is formed of the indirect transition semiconductor material, and has a second conductivity type which is a conductivity type different from the first conductivity type.

The second conductivity type semiconductor layer 2 is not required to have a sharp impurity concentration difference at a junction interface with respect to the second base material layer 3b described later, unlike the first conductivity type semiconductor layer 1, which is required to achieve tunneling movement of carriers at a junction interface with respect to the first base material layer 3a described later.

Accordingly, the second conductivity type semiconductor layer 2 may be configured by being selected as appropriate from a layer having a concentration distribution of impurities in which the junction interface side with respect to the second base material layer 3b is a low concentration region and another region is a high concentration region, a layer whose impurity concentration is uniformly a high concentration or other layers. Typically, a layer whose impurity concentration is uniformly a high concentration and a layer including a high concentration region of impurities are given.

In the description regarding the second conductivity type semiconductor layer 2, the impurity concentration at a high concentration means that the impurity concentration is 3×10¹⁹ cm⁻³ or more, with the upper limit of about 3×10²⁰ cm⁻³. Further, the impurity concentration at a low concentration means that the impurity concentration is less than 3×10¹⁹ cm⁻³, with the lower limit only required to be a concentration exceeding 0 cm⁻³.

Description matters common to the first conductivity type semiconductor layer 1 can be applied to the second conductivity type semiconductor layer 2 except that the conductivity type is different and how the impurity introduction setting is made is different. Description matters similar to the first conductivity type semiconductor layer 1 can be applied as the forming material and the forming method for the second conductivity type semiconductor layer 2.

The first conductivity type semiconductor layer 1 and the second conductivity type semiconductor layer 2 may be formed of forming materials of different types and forming methods of different types selected from the common description matters.

### <Intermediate Layer>

The intermediate layer is arranged so as to be sandwiched between the first conductivity type semiconductor layer 1 and the second conductivity type semiconductor layer 2, and is formed of at least one of an intrinsic semiconductor and an impurity-containing semiconductor having an impurity concentration lower than the impurity concentrations of the first conductivity type semiconductor layer 1 and the second conductivity type semiconductor layer 2.

Further, the intermediate layer is a layer having a laminate structure in which, assuming a first direction directed from the first conductivity type semiconductor layer 1 toward the second conductivity type semiconductor layer 2 as a laminating direction, on the first conductivity type semiconductor layer 1 serving as a base layer, at least one first base material layer 3a and at least one quantum well layer 4 are alternately laminated in the stated order, and the second base material layer 3b is laminated on the quantum well layer 4 on a side closest to the second conductivity type semiconductor layer 2 (the illustrated example of FIG. 2(a) is an example in which one first base material layer 3a and one quantum well layer 4 are laminated).

The laminating direction is an expression used when viewing the structure of the object, and does not mean a laminating direction in the method of forming the object. That is, as a matter of course, there may be employed, as the forming method, alternately laminating at least one first base material layer 3a and at least one quantum well layer 4 in the stated order on the first conductivity type semiconductor layer 1 and laminating the second base material layer 3b on the quantum well layer 4 on the side closest to the second conductivity type semiconductor layer 2 from the first conductivity type semiconductor layer 1 in the first direction (right direction of FIG. 2(a)), or there may be employed laminating the second base material layer 3b on the second conductivity type semiconductor layer 2 and alternately laminating at least one quantum well layer 4 and at least one first base material layer 3a in the stated order on the second base material layer 3b from the second conductivity type semiconductor layer 2 in a direction opposite to the first direction (left direction of FIG. 2(a)).

Further, in a case in which the second conductivity type semiconductor layer 2 is formed as a layer including a region having a high concentration of the impurities (partially including a region having a low concentration of the impurities) and the intermediate layer is formed as a layer of the impurity-containing semiconductor, the impurity concentration of the layer of the impurity-containing semiconductor being lower than the impurity concentration of the second conductivity type semiconductor layer 2 means that the impurity concentration of the layer of the impurity-containing semiconductor is lower than the impurity concentration in the region having a high concentration of the impurities in the second conductivity type semiconductor layer 2, and does not mean that the impurity concentration of the layer of the impurity-containing semiconductor is lower than the impurity concentration in the region having a low concentration of the impurities.

When the impurity concentration in the case in which the intermediate layer is formed as the layer of the impurity-containing semiconductor is a high concentration, it becomes difficult to bend the band in the ON state and to obtain a band structure suitable for band-to-band tunneling movement of carriers. Further, an unintended leakage current is liable to be caused in the OFF state. Thus, the impurity concentration of the intermediate layer is preferably as low as possible as compared to the impurity concentrations of the first conductivity type semiconductor layer 1 and the second conductivity type semiconductor layer 2. Specifically, it is preferred that the impurity concentration of the intermediate layer be one order of magnitude or more lower than the impurity concentrations of the first conductivity type semiconductor layer 1 and the second conductivity type semiconductor layer 2. For example, when the impurity concentrations of the first conductivity type semiconductor layer 1 and the second conductivity type semiconductor layer 2 are both 3×10¹⁹ cm⁻³, it is preferred that the impurity concentration of the intermediate layer be less than 3×10¹⁸ cm⁻³.

### -First Base Material Layer-

The first base material layer 3a is a layer that is formed of a first semiconductor material selected from the indirect transition semiconductor material and has a thickness in the first direction of from 0.5 nm to 20 nm.

When the thickness is less than 0.5 nm, there is a fear that a defective part may be caused in the layer so that the quantum well layer 4 is partially joined to the first conductivity type semiconductor layer 1, which is a high concentration impurity layer, to hinder the tunneling movement of carriers via a localized level formed by the quantum well layer 4. When the thickness exceeds 20 nm, a distance between the first conductivity type semiconductor layer 1 and the quantum well layer 4 exceeds a tunneling movable distance of the carriers, and the quantum well layer 4 hinders the tunneling movement of carriers via an intermediate energy level formed between the bands.

The first semiconductor material is not particularly limited and can be selected depending on the purpose. Examples of the first semiconductor material include Si, silicon germanium (SiGe), gallium phosphide (GaP), aluminum phosphide (AlP) and aluminum arsenide (AlAs). Of those, Si and SiGe are preferred because those components can be easily manufactured by utilizing many of the existing semiconductor element manufacturing facilities.

A method of forming the first base material layer 3a is not particularly limited and can be selected as appropriate depending on the purpose. Examples of the method include various methods of forming a publicly-known semiconductor layer.

An epitaxial growth method is given as a preferred forming method from the viewpoint of suppressing variations in electrical characteristics through use of a high-quality semiconductor layer. The epitaxial growth method uses a semiconductor layer having crystal orientation as a template.

Further, the first base material layer 3a may be formed as a single crystal layer, a polycrystalline layer or an amorphous layer of the first semiconductor material, but is preferred to be formed as a single crystal layer of the first semiconductor material from the viewpoint of suppressing variations in electrical characteristics through use of a high-quality semiconductor layer.

### -Second Base Material Layer-

The second base material layer 3b is a layer that is formed of a second semiconductor material selected from the indirect transition semiconductor material and has a thickness in the first direction of from 10 nm to 500 nm.

When the thickness is less than 10 nm, an unintended leakage current cannot be controlled through an ON/OFF operation. When the thickness exceeds 500 nm, the element size of the tunneling current driven element 10 is unnecessarily increased.

The second semiconductor material is not particularly limited and can be selected depending on the purpose. Examples of the second semiconductor material include Si, silicon germanium (SiGe), gallium phosphide (GaP), aluminum phosphide (AlP) and aluminum arsenide (AlAs). Of those, Si and SiGe are preferred because those components can be easily manufactured by utilizing many of the existing semiconductor element manufacturing facilities.

Further, the second semiconductor material may be a semiconductor material of the same type as the first semiconductor material or may be a semiconductor material of a type different therefrom, but is preferred to be a semiconductor material of the same type as the first semiconductor material from the viewpoint of simplifying the manufacturing process.

Further, matters described for the first base material layer 3a can be applied as the forming method and the crystallinity of the second base material layer 3b.

### -Quantum Well Layer-

The quantum well layer 4 is formed of a third semiconductor material selected from the indirect transition semiconductor material of a type different from the first semiconductor material and the second semiconductor material.

The third semiconductor material is selected from the indirect transition semiconductor material having a band structure of at least one of a first band structure and a second band structure. The first band structure has a valence band edge present at an energy position higher than valence band edges of the first semiconductor material and the second semiconductor material. The second band structure has a conduction band edge present at an energy position lower than conduction band edges of the first semiconductor material and the second semiconductor material.

The band structure means a band structure determined from a material-specific energy band value, and the band structure of the tunneling current driven element 10 can be confirmed by analyzing the constituent materials.

The third semiconductor material is not particularly limited and can be selected depending on the purpose. Examples of the third semiconductor material include Si, germanium (Ge), SiGe, SiC, silicon-germanium-carbon (SiGeC), AlAs and GaP. Of those, Si, Ge, SiGe, SiC, and SiGeC are preferred because those components can be easily manufactured by utilizing many of the existing semiconductor element manufacturing facilities.

A method of forming the quantum well layer 4 is not particularly limited and can be selected as appropriate depending on the purpose. Examples of the method include various methods of forming a publicly-known semiconductor layer.

An epitaxial growth method is given as a preferred forming method from the viewpoint of suppressing variations in electrical characteristics through use of a high-quality semiconductor layer. The epitaxial growth method uses a semiconductor layer having crystal orientation as a template.

Further, the quantum well layer 4 may be formed as a single crystal layer, a polycrystalline layer or an amorphous layer of the third semiconductor material, but is preferred to be formed as a single crystal layer of the third semiconductor material from the viewpoint of suppressing variations in electrical characteristics through use of a high-quality semiconductor layer.

The quantum well layer 4 is a layer having a thickness in the first direction of from 0.5 nm to 10 nm. With such a thickness, a quantum well that causes band-to-band tunneling movement can be formed between the bands.

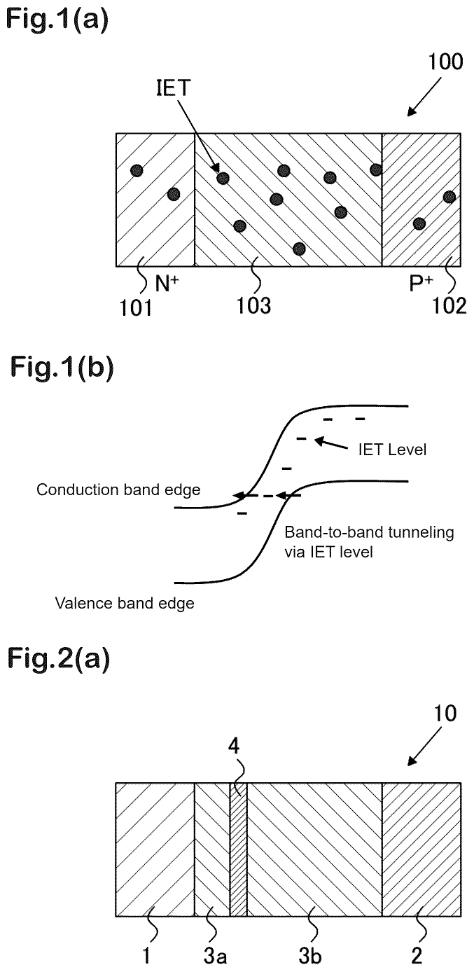

In the present invention, in place of the IET level of the tunneling current driven element (see FIG. 1(a) and FIG. 1(b)) in the related art, as illustrated in FIG. 2(b), a localized intermediate energy level obtained by the quantum well formed between the bands is used as a bridge to cause the band-to-band tunneling movement. FIG. 2(b) is a view for illustrating a band structure in the tunneling current driven element according to the present invention.

An energy depth (eV) of the quantum well formed by such a quantum well layer 4 can be intentionally controlled through selection of the third semiconductor material with respect to the first semiconductor material and the second semiconductor material. Further, a position of the quantum well in the band structure can be intentionally controlled by a forming location of the quantum well layer in the intermediate layer.

As a result, in the tunneling current driven element 10, unlike the IET levels (see FIG. 2(b)) formed by the IET impurities in a random distribution, the intermediate energy level for causing the band-to-band tunneling movement can be formed at an intended position, and the variations in electrical characteristics between elements can be suppressed while an effect of increasing the tunneling current is provided.

In the present invention, achievement of the band-to-band tunneling movement via the intermediate energy level formed by this quantum well is the core of the art. This means that selection of the third semiconductor material with respect to the first semiconductor material and the second semiconductor material is important. In the following, description is given first of a case in which the first semiconductor material and the second semiconductor material are semiconductor materials of the same type.

FIG. 3 shows band structures in general heterojunctions.

Among the band structures, in the band structure of Type-I in which energy levels at a valence band edge (Ev) and a conduction band edge (Ec) are shifted in opposite directions, in the first band structure from the left of FIG. 3 in which the energy levels at the valence band edge (Ev) and the conduction band edge (Ec) are shifted in directions separated away from each other, an energy level recessed in the forbidden band is not formed, and the quantum well is not formed.

In contrast, in the second band structure from the left of FIG. 3 in which the energy levels at the valence band edge (Ev) and the conduction band edge (Ec) are shifted in directions approaching each other, the quantum well is formed. That is, in the second band structure from the left of FIG. 3, the energy level recessed in the forbidden band is formed as the quantum well.

Further, in the two band structures of Type-II in which the energy levels at the valence band edge (Ev) and the conduction band edge (Ec) are shifted in the same direction, the energy level recessed in the forbidden band is formed as the quantum well on the side of any one of the valence band edge (Ev) and the conduction band edge (Ec). In this case, the band-to-band tunneling movement can be caused via the quantum well formed on the side of any one of the valence band edge (Ev) and the conduction band edge (Ec).

Accordingly, a combination of the third semiconductor material with respect to the first semiconductor material and the second semiconductor material includes a combination in which the second band structure from the left of FIG. 3 of Type-I is formed and a combination in which the band structure of Type-II is formed.

The first semiconductor material, the second semiconductor material and the third semiconductor material can be combined as appropriate from the materials described above in accordance with the above-mentioned principle. Among the combinations, the following combinations (1) to (6) are preferred because the tunneling current driven element can be easily manufactured through use of many of the existing semiconductor element manufacturing facilities:
(1) a combination in which the first semiconductor material and the second semiconductor material are Si and the third semiconductor material is Si₁₋ₓGeₓ, where “x” exceeds 0 and is less than 1;
(2) a combination in which the first semiconductor material and the second semiconductor material are Si and the third semiconductor material is Ge;
(3) a combination in which the first semiconductor material and the second semiconductor material are Si₁₋ₓGeₓ, where “x” exceeds 0 and is less than 1, and the third semiconductor material is Si_{1-y}Ge_{y}, where “y” is a value exceeding 0 and being less than 1 and further being larger than “x”;
(4) a combination in which the first semiconductor material and the second semiconductor material are Si₁₋ₓGeₓ, where “x” exceeds 0 and is less than 1, and the third semiconductor material is Ge;
(5) a combination in which the first semiconductor material and the second semiconductor material are Si and the third semiconductor material is Si₁₋ₓCₓ, where “x” exceeds 0 and is less than 1; and
(6) a combination in which the first semiconductor material and the second semiconductor material are Si and the third semiconductor material is Si_{1-x-y}GeₓC_{y}, where “x” exceeds 0 and is less than 1, “y” exceeds 0 and is less than 1, and “x+y” is less than 1.

Further, as the combination of the first semiconductor material, the second semiconductor material and the third semiconductor material, when the energy depth (eV) of the quantum well becomes deeper, the effect of increasing the tunneling current is more likely to be obtained.

That is, as illustrated in FIG. 4, in the band structure bent at the time of ON operation, as the energy depth (eV) of the quantum well becomes deeper with respect to a tunneling window (energy band surrounded by the dotted lines of FIG. 4, energy band in which the band-to-band tunneling movement is likely to be caused) which is a band-shaped energy band positioned between the conduction band edge on the first conductivity type semiconductor layer 1 side and the valence band edge on the second conductivity type semiconductor side, the probability of the band-to-band tunneling movement using the intermediate energy level as a bridge can be increased by positioning the intermediate energy level formed between the valence band edge and the conduction band edge by the quantum well layer 4 in the tunneling window. As a result, as compared to a case in which the energy depth (eV) of the quantum well is shallow, a case in which the energy depth (eV) of the quantum well is deep can obtain a larger effect of increasing the tunneling current. FIG. 4 is an explanatory view for illustrating the relationship between the tunneling window and the quantum well.

Thus, it is preferred that the first band structure in the band structure of the third semiconductor material (at least one of the first band structure and the second band structure) be a band structure in which the valence band edge is present at an energy position higher by more than 0.1 eV than the valence band edge having the highest energy position out of the first semiconductor material and the second semiconductor material, and it is preferred that the second band structure be a band structure in which the conduction band edge is present at an energy position lower by more than 0.1 eV than the conduction band edge having the lowest energy position out of the first semiconductor material and the second semiconductor material (this condition is hereinafter referred to as “suitable condition of the combination”).

As specific combinations satisfying the suitable condition of the combination, for example, the following combinations can be given:
a combination in which “x” is 0.12 or more and less than 1 in the combination (1) (combination in which the first semiconductor material and the second semiconductor material are Si and the third semiconductor material is Si₁₋ₓGeₓ, where “x” exceeds 0 and is less than 1);
the combination (2) (combination in which the first semiconductor material and the second semiconductor material are Si and the third semiconductor material is Ge);
a combination in which “y-x” is 0.12 or more in the combination (3) (combination in which the first semiconductor material and the second semiconductor material are Si₁₋ₓGeₓ, where “x” exceeds 0 and is less than 1, and the third semiconductor material is Si_{1-y}Ge_{y}, where “y” is a value exceeding 0 and being less than 1 and further being larger than “x”);
a combination in which “x” is 0.015 or more and less than 1 in the combination (5) (combination in which the first semiconductor material and the second semiconductor material are Si and the third semiconductor material is Si₁₋ₓCₓ, where “x” exceeds 0 and is less than 1); and
a combination in which “x” is about 0.06 and “y” is 0.015 or more in the combination (6) (combination in which the first semiconductor material and the second semiconductor material are Si and the third semiconductor material is Si_{1-x-y}GeₓC_{y}, where “x” exceeds 0 and is less than 1, “y” exceeds 0 and is less than 1, and “x+y” is less than 1).

In a case in which, although the suitable condition of the combination is not satisfied, the combination (4) (combination in which the first semiconductor material and the second semiconductor material are Si₁₋ₓGeₓ, where “x” exceeds 0 and is less than 1, and the third semiconductor material is Ge) is applied, when the Ge composition is increased, a difficulty level of the manufacturing process is increased, and an OFF-state current is also increased. Thus, it is preferred that “x” be less than 0.5.

Next, description is given of a case in which the first semiconductor material and the second semiconductor material are semiconductor materials of different types.

As described above, the first semiconductor material and the second semiconductor material are preferred to be semiconductor materials of the same type in terms of manufacture, but the first semiconductor material and the second semiconductor material may be semiconductor materials of different types in principle.

That is, as described above with reference to FIG. 3 and FIG. 4, in order to improve the probability of the band-to-band tunneling movement using the intermediate energy level formed by the quantum well layer 4 as a bridge, through selection of the third semiconductor material with respect to the first semiconductor material and the second semiconductor material, it is only required to form the energy level as the quantum well on the valence band edge side, form the energy level as the quantum well on the conduction band edge side, or form the energy level as the quantum well on both of the valence band edge side and the conduction band edge side. Those states can be achieved by performing band structure design between the first semiconductor material and the third semiconductor material and also between the second semiconductor material and the third semiconductor material.

For example, in the combination (3) (combination in which the first semiconductor material and the second semiconductor material are Si₁₋ₓGeₓ, where “x” exceeds 0 and is less than 1, and the third semiconductor material is Si_{1-y}Ge_{y}, where “y” is a value exceeding 0 and being less than 1 and further being larger than “x”), it is only required that the first semiconductor material and the second semiconductor material be different composition materials having different values of “x” and the third semiconductor material be a different composition material having a value of “y” larger than those two values of “x”.

In the present invention, it is important to prevent the quantum well layer 4 from coming into contact with the first conductivity type semiconductor layer 1 which is a high concentration impurity layer.

That is, as is understood from FIG. 4, when the quantum well layer 4 is formed in contact with the first conductivity type semiconductor layer 1, the band-to-band tunneling movement via the intermediate energy level of the quantum well cannot be achieved, and the band-to-band tunneling movement is caused by a direct tunneling phenomenon having a low probability. Thus, the effect of increasing the tunneling current cannot be expected.

In the present invention, the first base material layer 3a plays a role of preventing the quantum well layer 4 and the first conductivity type semiconductor layer 1 from coming into contact with each other.

The first base material layer 3a has been described above as a layer having a thickness in the first direction of 20 nm or less from the relationship of the tunneling movable distance of the carriers, but the first base material layer 3a is preferred to be a layer having a thickness in the first direction of 8 nm or less further from the relationship of the tunneling window.

That is, as is understood from FIG. 4, when the distance between the first conductivity type semiconductor layer 1 and the quantum well layer 4 to be controlled by the thickness of the first base material layer 3a becomes excessively long, the quantum well obtained by the quantum well layer 4 is positioned on the second conductivity type semiconductor layer 2 side and is excessively separated away from the first conductivity type semiconductor layer 1. As a result, an energy region of the quantum well overlapping the tunneling window is reduced, and thus the probability of the band-to-band tunneling movement via the intermediate energy level is liable to be reduced.

### Modification Example

Next, a modification example of the tunneling current driven element 10 is described with reference to FIG. 5.

As illustrated in FIG. 5, in a tunneling current driven element 10′ according to the modification example, unlike the tunneling current driven element 10 in which the intermediate layer includes the first base material layer 3a, the quantum well layer 4 and the second base material layer 3b, the intermediate layer includes a first base material layer 3a, a quantum well layer 4, a first base material layer 3a′, a quantum well layer 4′ and a second base material layer 3b.

In this case, the first base material layer 3a′ and the quantum well layer 4′ are similarly formed by applying the matters described for the first base material layer 3a and the quantum well layer 4.

The intermediate layer may have a laminate structure obtained by alternately and repeatedly laminating the first base material layer 3a and the quantum well layer 4 as described above.

The first base material layer 3a′ may be formed of a material of the same type as the first base material layer 3a, or may be formed of a material of a type different from the first base material layer 3a as long as the material is selected from the first semiconductor forming material. Further, the quantum well layer 4′ may be formed of a material of the same type as the quantum well layer 4, or may be formed of a material of a type different from the quantum well layer 4 as long as the material is selected from the third semiconductor forming material.

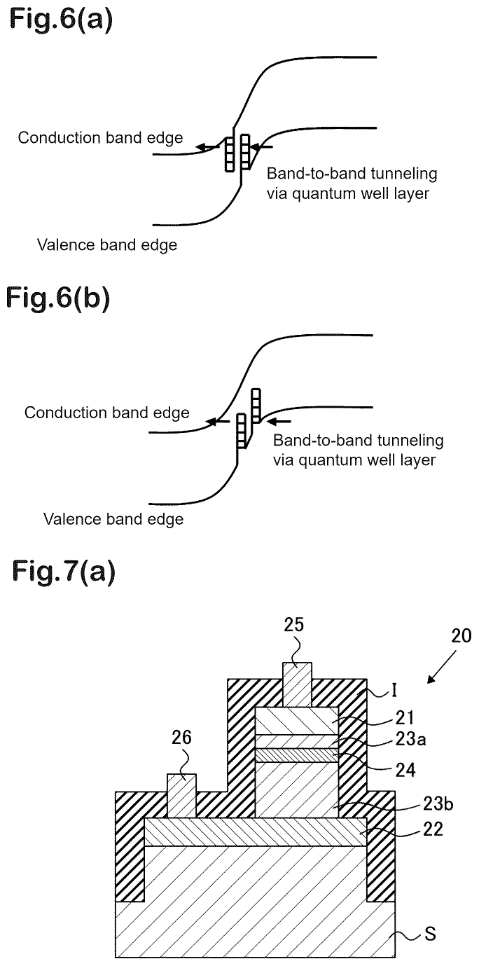

When the quantum well layer 4′ is formed of the third semiconductor forming material of a type different from the quantum well layer 4, in the examples of the band structures illustrated in FIG. 6(a) and FIG. 6(b), an effect of increasing the tunneling current by the band-to-band tunneling movement via the intermediate energy level can be obtained. When the quantum well layer 4′ is formed of the second semiconductor forming material of the same type as the quantum well layer 4, in the band structure illustrated in FIG. 6(b), an effect of increasing the tunneling current by the band-to-band tunneling movement via the intermediate energy level can be obtained. FIG. 6(a) is a view (1) for illustrating a band structure example in the ON state of the tunneling current driven element according to the modification example, and FIG. 6(b) is a view (2) for illustrating a band structure example in the ON state of the tunneling current driven element according to the modification example.

### [Tunneling Diode]

The tunneling current driven element of the present invention can be applied to a publicly-known tunneling diode (for example, a PIN tunneling diode) in which a low impurity concentration layer is arranged between an n-type semiconductor layer and a p-type semiconductor layer. The low impurity concentration layer is formed of at least one of an intrinsic semiconductor and an impurity-containing semiconductor having an impurity concentration lower than impurity concentrations of the n-type semiconductor layer and the p-type semiconductor layer. Thus, the effect of increasing the tunneling current can be obtained.

With reference back to FIG. 2(a), the tunneling current driven element in a case of being applied to the tunneling diode is described.

The tunneling current driven element 10 in the case of being applied to the tunneling diode has at least one of a first element structure and a second element structure. The first element structure has a configuration in which the n-type semiconductor layer is formed of the first conductivity type semiconductor layer 1 having the first conductivity type being the “n” type, the p-type semiconductor layer is formed of the second conductivity type semiconductor layer 2 having the second conductivity type being the “p” type, and the low impurity concentration layer is formed of the intermediate layer (first base material layer 3a, quantum well layer 4 and second base material layer 3b). The second element structure has a configuration in which the p-type semiconductor layer is formed of the first conductivity type semiconductor layer 1 having the first conductivity type being the “p” type, the n-type semiconductor layer is formed of the second conductivity type semiconductor layer 2 having the second conductivity type being the “n” type, and the low impurity concentration layer is formed of the intermediate layer (first base material layer 3a, quantum well layer 4 and second base material layer 3b).

With those configurations, the effect of increasing the tunneling current can be obtained only by changing, for example, the configuration of the low impurity concentration layer with respect to a publicly-known tunneling diode (for example, the PIN tunneling diode) and arranging the quantum well layer 4 in the layer having the low impurity concentration layer as the base material. Thus, those configurations are extremely suitable for practical use.

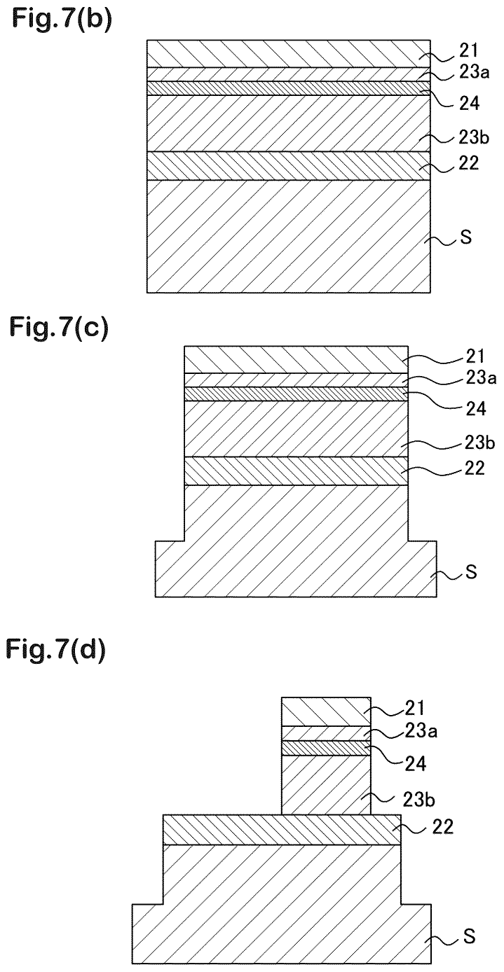

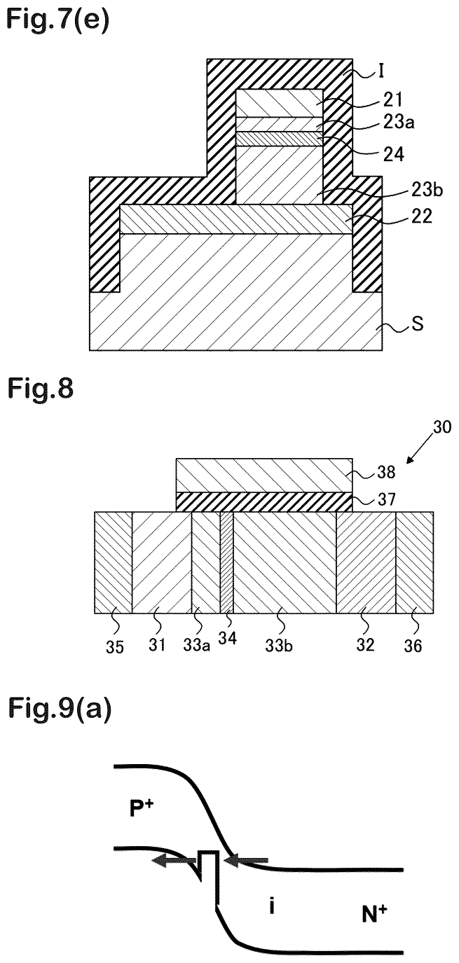

A configuration example of a tunneling current driven element having a configuration equivalent to that of the tunneling current driven element 10, which is a more practical configuration for the case of being applied to the tunneling diode, is illustrated in FIG. 7(a).

As illustrated in FIG. 7(a), a tunneling current driven element 20 has a laminate structure in which, on a support substrate S, a second conductivity type semiconductor layer 22, a second base material layer 23b, a quantum well layer 24, a first base material layer 23a and a first conductivity type semiconductor layer 21 are laminated in the stated order. Further, the laminate structure is covered with an interlayer insulating film I for wiring, and a metal electrode 25 connected to the first conductivity type semiconductor layer 21 and a metal electrode 26 connected to the second conductivity type semiconductor layer 22 are formed for wiring connection. Thus, an operation of the tunneling diode can be achieved as a two-terminal device.

This tunneling current driven element 20 is formed as a vertical element having a current direction in a direction perpendicular to the surface of the support substrate S. When the respective layers of the second conductivity type semiconductor layer 22, the second base material layer 23b, the quantum well layer 24, the first base material layer 23a and the first conductivity type semiconductor layer 21 are formed by a publicly-known chemical vapor deposition epitaxial growth method through use of the support substrate S having crystal orientation as a base, the layers can be formed as high-quality layers having few defects and aligned crystal orientations. Further, the tunneling current driven element 20 can be practically manufactured through use of existing facilities.

The tunneling current driven element 20 may be manufactured with the laminating order being reversed from that in the illustrated example so as to have a laminate structure in which, on the support substrate S, the first conductivity type semiconductor layer 21, the first base material layer 23a, the quantum well layer 24, the second base material layer 23b and the second conductivity type semiconductor layer 22 are laminated in the stated order.

A specific example for manufacturing the tunneling current driven element 20 is described with reference to FIG. 7(b) to FIG. 7(e). FIG. 7(b) to FIG. 7(e) are schematic cross-sectional explanatory views (1) to (4) for illustrating the outline of the process of manufacturing the tunneling current driven element 20.

First, on the support substrate S, the respective layers of the second conductivity type semiconductor layer 22, the second base material layer 23b, the quantum well layer 24, the first base material layer 23a and the first conductivity type semiconductor layer 21 are successively grown by a publicly-known chemical vapor deposition epitaxial growth method (see FIG. 7(b)).

Next, by a publicly-known lithography processing method or other methods, parts of the support substrate S, the second conductivity type semiconductor layer 22, the second base material layer 23b, the quantum well layer 24, the first base material layer 23a and the first conductivity type semiconductor layer 21 are removed by etching so that element isolation is achieved (see FIG. 7(c)).

Next, similarly by a publicly-known lithography processing method or other methods, parts of the second base material layer 23b, the quantum well layer 24, the first base material layer 23a and the first conductivity type semiconductor layer 21 are removed by etching so that a mesa structure is formed (see FIG. 7(d)).

Next, by a publicly-known chemical vapor deposition method or other methods, a publicly-known insulating material is deposited from a position above the first conductivity type semiconductor layer 21 so that the interlayer insulating film I is formed so as to cover the second conductivity type semiconductor layer 22, the second base material layer 23b, the quantum well layer 24, the first base material layer 23a and the first conductivity type semiconductor layer 21 (see FIG. 7(e)).

Finally, by a publicly-known lithography processing method or other methods, contact holes are formed in the interlayer insulating film I, and then the metal electrodes 25 and 26 are formed at positions of the contact holes by a publicly-known physical vapor deposition method or other methods. Thus, the tunneling current driven element 20 is manufactured (see FIG. 7(a)).

### [Tunneling Field Effect Transistor]

The tunneling current driven element of the present invention can be applied to a publicly-known tunneling field effect transistor in which a channel region is formed between a source region and a drain region and a gate electrode is formed above the channel region through intermediation of a gate insulating film. Thus, the effect of increasing the tunneling current can be obtained.

With reference to FIG. 8, the tunneling current driven element in a case of being applied to the tunneling field effect transistor is described.

As illustrated in FIG. 8, in a tunneling current driven element 30, the source region is formed of a first conductivity type semiconductor layer 31, the drain region is formed of a second conductivity type semiconductor layer 32, and the channel region is formed of the intermediate layer. The first conductivity type semiconductor layer 31 and the second conductivity type semiconductor layer 32 are formed to conform to the first conductivity type semiconductor layer 1 and the second conductivity type semiconductor layer 2 described in the tunneling current driven element, and the intermediate layer is formed of a first base material layer 33a, a quantum well layer 34 and a second base material layer 33b confirming to the first base material layer 3a, the quantum well layer 4 and the second base material layer 3b described in the tunneling current driven element 10. Respective members of a source electrode 35 connected to the first conductivity type semiconductor layer 31 (the source region), a drain electrode 36 connected to the second conductivity type semiconductor layer 32 (the drain region), a gate insulating film 37 and a gate electrode 38 are formed similarly to respective corresponding members in a publicly-known tunneling field effect transistor.

With this configuration, the effect of increasing the tunneling current can be obtained only by changing, for example, the configuration of the channel region with respect to a publicly-known tunneling field effect transistor and arranging the quantum well layer 34 in the layer having the component of the channel region as the base material. Thus, this configuration is extremely suitable for practical use.

Further, according to the tunneling current driven element 30, a complementary operation can be performed similarly to the publicly-known tunneling field effect transistor.

That is, an operation as an N-type tunneling field effect transistor can be achieved when the conductivity type of the first conductivity type semiconductor layer 31 (the source region) is set to the “p” type and the conductivity type of the second conductivity type semiconductor layer 32 (the drain region) is set to the “n” type.

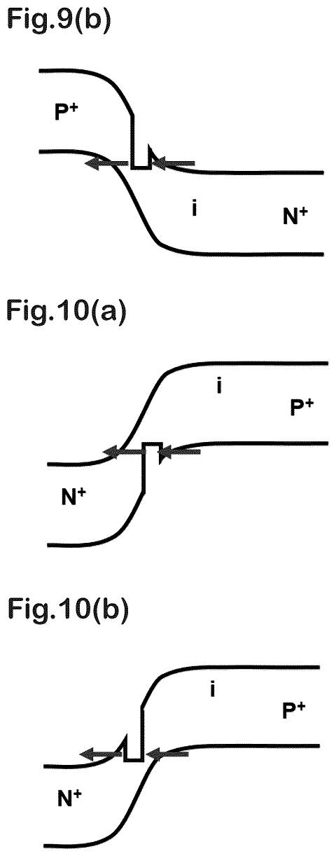

More specifically, as the intermediate layer (the channel region), through selection of the third semiconductor material with respect to the first semiconductor material and the second semiconductor material, whether to form an energy level recessed in the forbidden band as the quantum well on the valence band edge side (see FIG. 9(a)), whether to form an energy level recessed in the forbidden band as the quantum well on the conduction band edge side (see FIG. 9(b)), whether to form both of those energy levels (see the second structure from the left of FIG. 3 and FIG. 6(a)), or the like is selected so that the operation as the N-type tunneling field effect transistor whose tunneling current is increased is achieved. FIG. 9(a) is an explanatory band structure view (1) for illustrating the operation of the N-type tunneling field effect transistor, and FIG. 9(b) is an explanatory band structure view (2) for illustrating the operation of the N-type tunneling field effect transistor.

Meanwhile, when the polarities are changed so that the conductivity type of the first conductivity type semiconductor layer 31 (the source region) is set to the “n” type and the conductivity type of the second conductivity type semiconductor layer 32 (the drain region) is set to the “p” type, an operation as a P-type tunneling field effect transistor can be achieved.

More specifically, as the intermediate layer (the channel region), through selection of the third semiconductor material with respect to the first semiconductor material and the second semiconductor material, whether to form an energy level recessed in the forbidden band as the quantum well on the valence band edge side (see FIG. 10(a)), whether to form an energy level recessed in the forbidden band as the quantum well on the conduction band edge side (see FIG. 10(b)), whether to form both of those energy levels (see FIG. 6(a)), or the like is selected so that the operation as the P-type tunneling field effect transistor whose tunneling current is increased is achieved. FIG. 10(a) is an explanatory band structure view (1) for illustrating the operation of the P-type tunneling field effect transistor, and FIG. 10(b) is an explanatory band structure view (2) for illustrating the operation of the P-type tunneling field effect transistor.

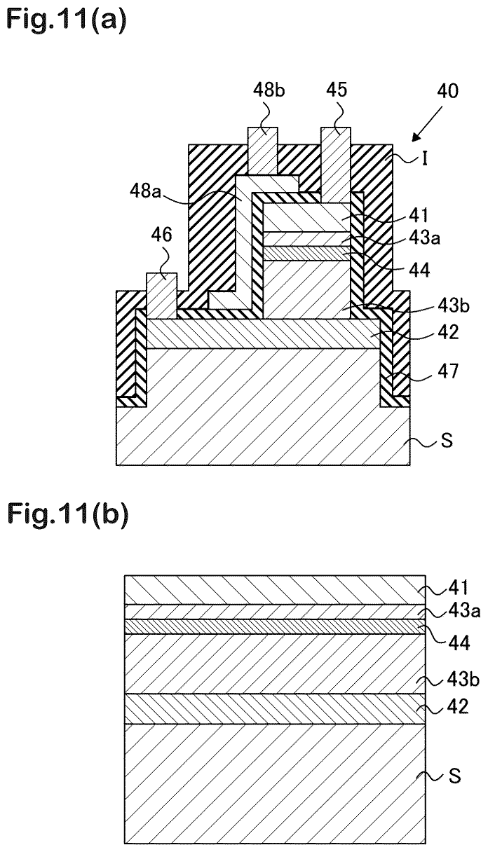

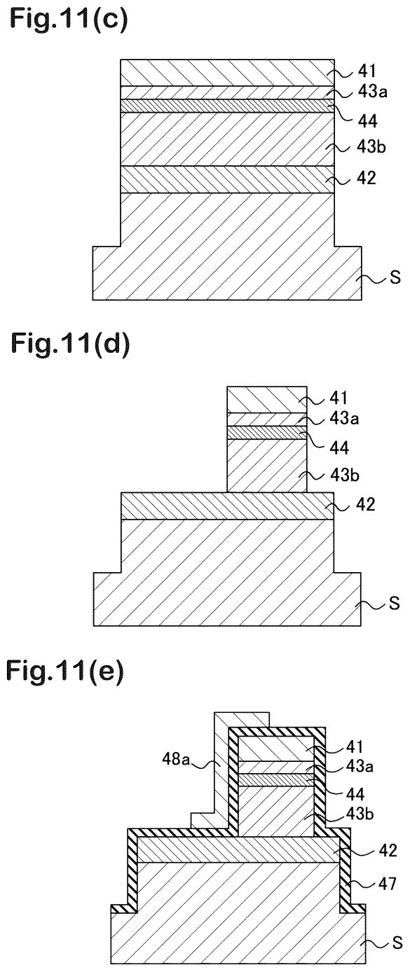

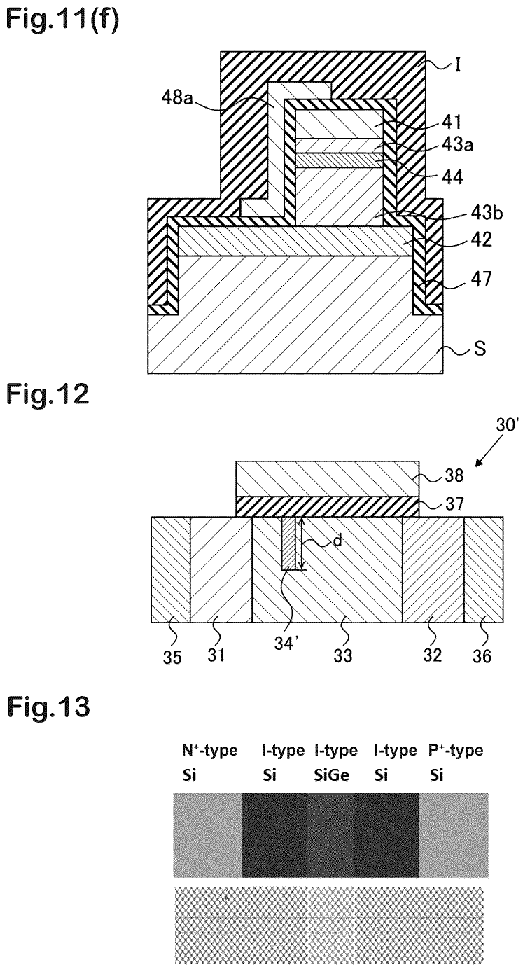

A configuration example of a tunneling current driven element having a configuration equivalent to that of the tunneling current driven element 30, which is a more practical configuration for the case of being applied to the tunneling field effect transistor, is illustrated in FIG. 11(a).

As illustrated in FIG. 11(a), a tunneling current driven element 40 has a laminate structure in which, on the support substrate S, a second conductivity type semiconductor layer 42, a second base material layer 43b, a quantum well layer 44, a first base material layer 43a and a first conductivity type semiconductor layer 41 are laminated in the stated order. Further, a gate insulating film 47 and a gate electrode 48a (and additionally a metal electrode 48b for terminal connection) are formed, and the laminate structure is covered with the interlayer insulating film I for wiring. In addition, a source electrode 45 connected to the first conductivity type semiconductor layer 41 and a drain electrode 46 connected to the second conductivity type semiconductor layer 42 are formed for wiring connection. Thus, an operation of the tunneling field effect transistor can be achieved as a three-terminal device.

This tunneling current driven element 40 is formed as a vertical element having a current direction in a direction perpendicular to the surface of the support substrate S. When the respective layers of the second conductivity type semiconductor layer 42, the second base material layer 43b, the quantum well layer 44, the first base material layer 43a and the first conductivity type semiconductor layer 41 are formed by a publicly-known chemical vapor deposition epitaxial growth method through use of the support substrate S having crystal orientation as a base, the layers can be formed as high-quality layers having few defects and aligned crystal orientations. Further, the tunneling current driven element 40 can be practically manufactured through use of existing facilities.

The tunneling current driven element 40 may be manufactured with the laminating order being reversed from that in the illustrated example so as to have a laminate structure in which, on the support substrate S, the first conductivity type semiconductor layer 41, the first base material layer 43a, the quantum well layer 44, the second base material layer 43b and the second conductivity type semiconductor layer 42 are laminated in the stated order.

A specific example for manufacturing the tunneling current driven element 40 is described with reference to FIG. 11(b) to FIG. 11(f). FIG. 11(b) to FIG. 11(f) are schematic cross-sectional explanatory views (1) to (5) for illustrating the outline of the process of manufacturing the tunneling current driven element 40.

First, on the support substrate S, the respective layers of the second conductivity type semiconductor layer 42, the second base material layer 43b, the quantum well layer 44, the first base material layer 43a and the first conductivity type semiconductor layer 41 are successively grown by a publicly-known chemical vapor deposition epitaxial growth method (see FIG. 11(b)).

Next, by a publicly-known lithography processing method or other methods, parts of the support substrate S, the second conductivity type semiconductor layer 42, the second base material layer 43b, the quantum well layer 44, the first base material layer 43a and the first conductivity type semiconductor layer 41 are removed by etching so that element isolation is achieved (see FIG. 11(c)).

Next, similarly by a publicly-known lithography processing method or other methods, parts of the second base material layer 43b, the quantum well layer 44, the first base material layer 43a and the first conductivity type semiconductor layer 41 are removed by etching so that a mesa structure is formed (see FIG. 11(d)). Although not shown, etching may be performed such that the etching depth at the time of forming the mesa structure is set deeper so that a part of a side surface of the second conductivity type semiconductor layer 42 is exposed.

Next, by a publicly-known chemical vapor deposition method or other methods, a publicly-known insulating material is deposited from a position above the first conductivity type semiconductor layer 41 so that the gate insulating film 47 is formed so as to cover the second conductivity type semiconductor layer 42, the second base material layer 43b, the quantum well layer 44, the first base material layer 43a and the first conductivity type semiconductor layer 41. Then, by a publicly-known evaporation method or other methods, the gate electrode 48a is formed so as to cover a side surface position of the intermediate layer (second base material layer 43b, quantum well layer 44 and first base material layer 43a) formed as the channel region. Thus, a gate stack is formed (see FIG. 11(e)).

Next, by a publicly-known chemical vapor deposition method or other methods, a publicly-known insulating material is deposited from above so that the interlayer insulating film I is formed so as to cover the gate insulating film 47 and the gate electrode 48a (see FIG. 11(f)).

Finally, by a publicly-known lithography processing method or other methods, contact holes are formed in the interlayer insulating film I and the gate insulating film 47, and then the metal electrodes 45, 46 and 48b are formed at positions of the contact holes by a publicly-known physical vapor deposition method or other methods. Thus, the tunneling current driven element 40 is manufactured (see FIG. 11(a)).

In the illustrated example, the gate insulating film 47 and the gate electrode 48a form the gate stack, but the gate stack may be formed in a double-gate structure in which a gate electrode is further arranged on a surface of the intermediate layer on a side opposite to a surface thereof on a side on which the gate electrode 48a is arranged so as to conform to the structure of the publicly-known tunneling field effect transistor. As another example, the gate stack may be formed in an all-around structure covering the entire periphery of the intermediate layer.

### Modification Example

Next, a modification example of the tunneling current driven element 30 (see FIG. 8) is described with reference to FIG. 12.

As illustrated in FIG. 12, a tunneling current driven element 30′ according to the modification example has a configuration in which a quantum well layer 34′ is arranged in place of the quantum well layer 34 in the tunneling current driven element 30 in which a length in a second direction (down direction of FIG. 8) orthogonal to the first direction (right direction of FIG. 8) as viewed from a position in contact with the gate insulating film 37 is aligned with the length of the first base material layer 33a (and the second base material layer 33b). The quantum well layer 34′ has a length (“d” of FIG. 12) in the second direction (down direction of FIG. 12) shorter than a length of a base material layer 33.

In this configuration, when a line (path of currents) passing through the position of the quantum well layer 34′ in the first direction directed from the first conductivity type semiconductor layer 31 toward the second conductivity type semiconductor layer 32 is viewed, this line passes through the base material layer 33 twice. A region of the base material layer 33 through which the line first passes can be regarded as being equivalent to the first base material layer 33a, and a region of the base material layer 33 through which the line passes the second time can be regarded as being equivalent to the second base material layer 33b.

As described above, in the present invention, a laminating relationship among the first base material layer, the quantum well layer and the second base material layer in the first direction means a laminating relationship on the line (path of currents) passing through the position of the quantum well layer in the first direction directed from the first conductivity type semiconductor layer toward the second conductivity type semiconductor layer, and the quantum well layer is not required to be laminated on the first base material layer (and the second base material layer) with the lengths in the second direction being aligned.

A region in which a band-to-band tunneling phenomenon is caused between the first conductivity type semiconductor layer 31 and the intermediate layer (the channel region) due to a gate voltage applied to the gate electrode 38 is only up to a region advancing by about 5 nm in the second direction (down direction of FIG. 12) as viewed from one surface position of the intermediate layer (the channel region) in contact with the gate insulating film 37 toward another surface of the intermediate layer on a side on which no gate insulating film 37 is arranged. As long as the length (“d” of FIG. 12) of the quantum well layer 34′ in the second direction (down direction of FIG. 12) is at least 5 nm, the effect of increasing the tunneling current is sufficiently exerted. The upper limit of the length “d” is a length aligned with the length of the base material layer 33 in the second direction, and the length of the base material layer 33 in the second direction conforms to the length of the channel region in the second direction in the publicly-known tunneling field effect transistor and has no particular restriction.

This point is different from the band-to-band tunneling phenomenon caused at the entire junction surface of the quantum well layer 4 in contact with the first base material layer 3a in the tunneling current driven element 10 (see FIG. 2(a)) in a case of being used as the tunneling diode. In the tunneling current driven element 10 in the case of being used as the tunneling diode, as illustrated in FIG. 2(a), it is preferred that the length of the quantum well layer 4 in the second direction (down direction of FIG. 2(b)) orthogonal to the first direction (right direction of FIG. 2(a)) be aligned with the length of the first base material layer 3a (and the second base material layer 3b).

### Example

### (Simulation)

In order to confirm the effectiveness of the present invention, a simulation test regarding an increase of the tunneling current through use of the tunneling diode as a target was performed.

This simulation test was executed by obtaining an energy band structure in the vicinity of a tunneling interface through first-principles calculation, and calculating the tunneling current based on this energy band structure. For the calculation of the energy band structure, the software (Vienna Ab initio Simulation Package (VASP)) developed mainly by University of Vienna was used, and for the calculation of the tunneling current, the software independently developed by the applicant of this application (National University Corporation Chiba University) was used.

The test target model is a PIN-type tunneling diode illustrated in FIG. 13. The first conductivity type semiconductor layer is formed of an N⁺-type Si semiconductor layer, and the second conductivity type semiconductor layer is formed of a P⁺-type Si semiconductor layer. Regarding the intermediate layer, the first base material layer and the second base material layer are formed of Si intrinsic semiconductor layers, and the quantum well layer is formed of a SiGe quantum well layer formed of an intrinsic SiGe (Ge composition of 60 atom %; Si_{0.40}Ge_{0.60}) semiconductor. FIG. 13 is a view for illustrating the test target model of the simulation test.

In the test target model, a distance between the N⁺-type Si semiconductor layer and the P⁺-type Si semiconductor layer was set to 10 nm, and the thickness of the SiGe quantum well layer in the first direction (right direction of FIG. 13) was set to 2.3 nm. Further, as a comparison model, a state having no SiGe quantum well layer was set, and a Si intrinsic semiconductor layer having a thickness in the first direction of 10 nm was set as the intermediate layer between the N⁺-type Si semiconductor layer and the P⁺-type Si semiconductor layer.

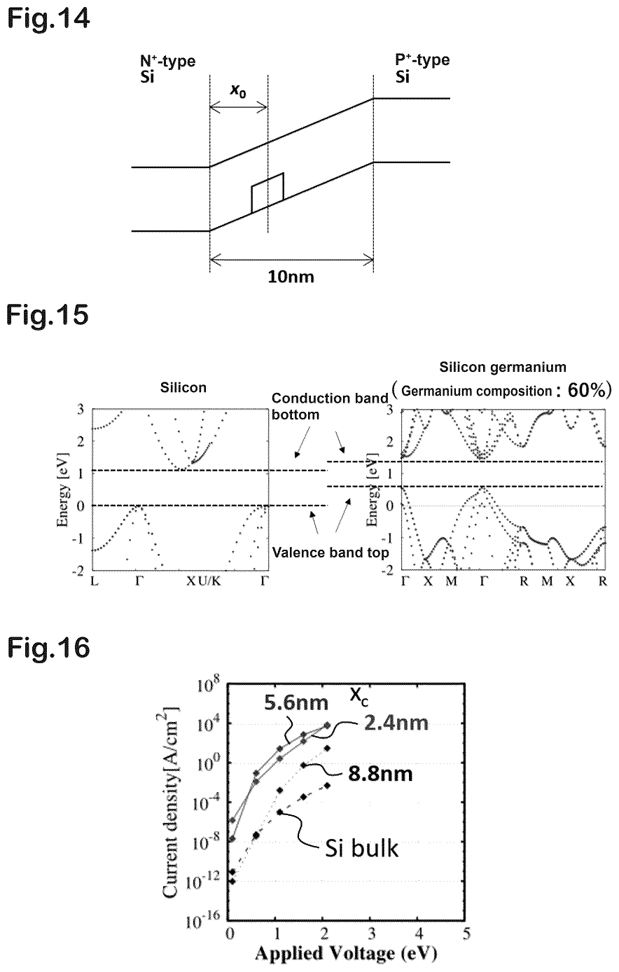

Further, the distance (x₀) between the N⁺-type Si semiconductor layer and the center position of the SiGe quantum well layer in the first direction was set to be variable by changing the forming position of the SiGe quantum well layer in the Si intrinsic semiconductor layer serving as a base material (see FIG. 14). The distance (x₀) was set to three patterns of 2.4 nm, 5.6 nm and 8.8 nm. FIG. 14 is an explanatory view for illustrating a setting state of the distance (x₀) between the N⁺-type Si semiconductor layer and the center position of the SiGe quantum well layer in the first direction.

Further, through use of the SiGe quantum well layer as an epitaxial growth layer, in consideration of the fact that the crystal lattice size of SiGe is larger than the crystal lattice size of Si, an in-plane two-axis (up-down direction and front-depth direction of the drawing sheet of FIG. 13) compressive strain is applied to the SiGe crystal lattice in the SiGe quantum well layer. Thus, there was achieved a state in which, while the SiGe crystal lattice in a direction orthogonal to the two-axis directions extended without a strain, the lattice size in the two-axis directions matched the lattice size of the base material of Si.

FIG. 15 shows an energy band structure of each of Si and SiGe (Ge composition of 60%) obtained through the simulation test.

As shown in FIG. 15, the valence band top of SiGe is positioned above the valence band top of Si, and it is confirmed that the quantum well can be formed by the Si/SiGe/Si laminate structure.

FIG. 16 shows characteristics of tunneling currents of the PIN-type tunneling diode in the simulation test.

As shown in FIG. 16, there can be confirmed a tendency that all of the three models having x₀ of 2.4 nm, 5.6 nm and 8.8 nm have remarkedly increased tunneling currents as compared to the comparison model (Si bulk) having no SiGe quantum well layer.

Among the models, it is confirmed that the models having x₀ of 2.4 nm and 5.6 nm can obtain tunneling currents larger than that of the model having x₀ of 8.8 nm.

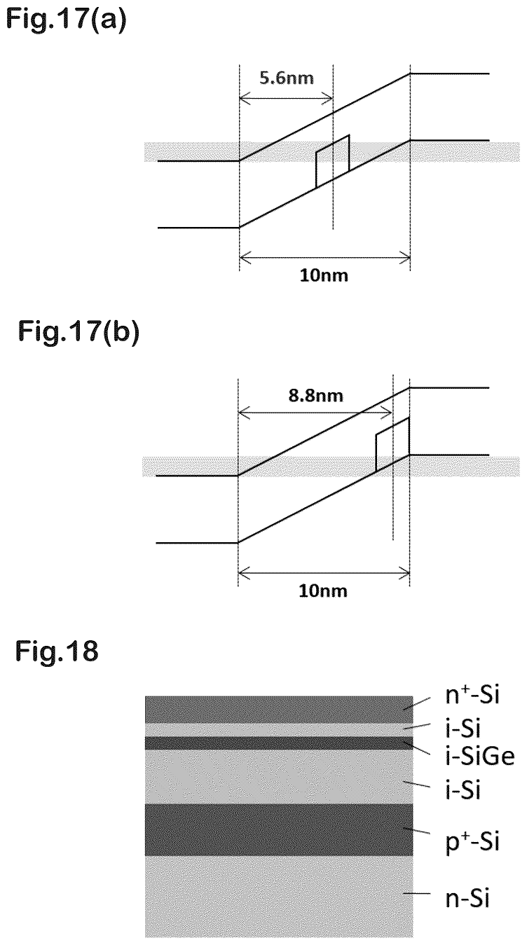

The reason therefor is because, in the model having x₀ of 8.8 nm, the quantum well obtained by the SiGe quantum well layer is positioned on the P⁺-type Si semiconductor layer side and is excessively separated away from the N⁺-type Si semiconductor layer, and thus the energy level for tunneling movement is less liable to be formed in the tunneling window indicated by dark bands of FIG. 17(a) and FIG. 17(b).

From this fact, it is concluded that the models having x₀ of 2.4 nm and 5.6 nm are more suitable. On the actual element, 8 nm or less is more suitable as the thickness of the first base material layer (intrinsic Si semiconductor layer on the left side of FIG. 13) for controlling this distance x₀.

FIG. 17(a) is a view for illustrating a positional relationship between the tunneling window and the quantum well obtained by the SiGe quantum well layer in the model having x₀ of 5.6 nm, and FIG. 17(b) is a view for illustrating a positional relationship between the tunneling window and the quantum well obtained by the SiGe quantum well layer in the model having x₀ of 8.8 nm.

### Example

In order to confirm the effectiveness of the simulation results, the tunneling current driven element was manufactured and its performance was evaluated.

The tunneling current driven element according to Example had an element structure of the tunneling diode, and was manufactured in a configuration illustrated in FIG. 18. Specifically, the tunneling current driven element according to Example was manufactured as follows.

First, an n-type (100) crystal orientation silicon support substrate (manufactured by GlobalWafers Co., Ltd., phosphorus-doped silicon wafer having a diameter of 200 mm manufactured by a Czochralski method (CZ method), “n-Si” of FIG. 18) was prepared.

Next, a p⁺-type Si semiconductor layer (“p⁺-Si” of FIG. 18) in which boron (B) was doped at a concentration of 7×10¹⁹ cm⁻³ was formed as the second conductivity type semiconductor layer on the silicon support substrate so as to have a thickness of 200 nm.

Next, an intrinsic Si semiconductor layer (“i-Si” of the lower side of FIG. 18) was formed as the second base material layer on the p⁺-type Si layer so as to have a thickness of 200 nm.

Next, an intrinsic SiGe (Ge composition of 60 atom %; Si_{0.40}Ge_{0.60}) semiconductor layer (“i-SiGe” of FIG. 18) was formed as the quantum well layer on the intrinsic Si semiconductor layer so as to have a thickness of 6 nm. A composition ratio of Si and Ge in the intrinsic SiGe semiconductor layer was checked through use of an analyzing apparatus (manufactured by HORIBA JOBIN YVON, UVISEL, M200-FUV-FGMS-HNSTSS).

Next, an intrinsic Si semiconductor layer (“i-Si” on the upper side of FIG. 18) was formed again as the first base material layer on the intrinsic SiGe semiconductor layer so as to have a thickness of 6 nm.

Next, an n⁺-type Si semiconductor layer (“n⁺-Si” of FIG. 18) in which phosphorus (P) was doped at a concentration of 4×10¹⁹ cm⁻³ was formed as the first conductivity type semiconductor layer on the intrinsic Si semiconductor layer (“i-Si” on the upper side of FIG. 18) serving as the first base material layer, so as to have a thickness of 100 nm.

Those layers on the silicon support substrate were formed by successively growing the layers by a chemical vapor deposition epitaxial growth method through use of a chemical vapor deposition apparatus (ASM International N.V., Epsilon 2000).

In the manner described above, the tunneling current driven element according to Example was manufactured.

### Comparative Example

A tunneling current driven element according to Comparative Example was manufactured similarly to the tunneling current driven element according to Example except that the intrinsic SiGe semiconductor layer serving as the quantum well layer was not formed and the intrinsic Si semiconductor layer serving as the first base material layer and the second base material layer was collectively formed on the p⁺-type Si layer so as to have a thickness of 206 nm.

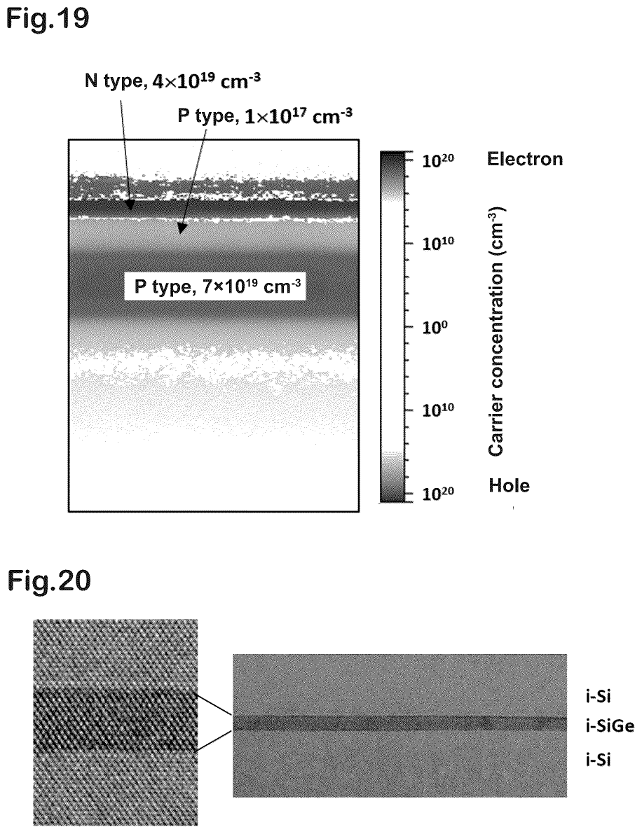

FIG. 19 shows a carrier (electron or hole) density distribution in the tunneling current driven element according to Comparative Example. This carrier density distribution was acquired by performing evaluation through scanning capacitance microscopy (SCM) and scanning microwave microscopy (SMM) by using a microscope apparatus (manufactured by Bruker AXS GmbH, NanoScope V/Dimension Icon).

This evaluation was performed for the purpose of evaluating the carrier concentration, and was performed for, as a target, the tunneling current driven element according to Comparative Example in which the intrinsic SiGe semiconductor layer serving as the quantum well layer was not formed, in order to improve the analysis accuracy.

In FIG. 19, a region indicated as “P type, 1×10¹⁷ cm⁻³” corresponds to the intrinsic Si semiconductor layer serving as the first base material layer and the second base material layer.

As illustrated in FIG. 19, although unexpected carrier generation is caused in the intrinsic Si semiconductor layer, its concentration is sufficiently lower than the p⁺-type Si semiconductor layer (7×10¹⁹ cm⁻³) and the n⁺-type Si semiconductor layer (4×10¹⁹ cm⁻³), and it is confirmed that the function as the PIN-type tunneling diode is achieved.

FIG. 20 shows a TEM image of a laminate structure part of the intermediate layer (i-Si/i-SiGe/i-Si) of the tunneling current driven element according to Example, which has been taken by a cross-sectional transmission electron microscope (TEM, manufactured by Hitachi High-Tech Corporation, H-9500).

As illustrated in FIG. 20, it is confirmed that the intrinsic SiGe semiconductor layer serving as the quantum well layer is formed without defects and with a high quality in accordance with the crystal orientation of the intrinsic Si semiconductor layer (“i-Si” on the lower side of FIG. 18).

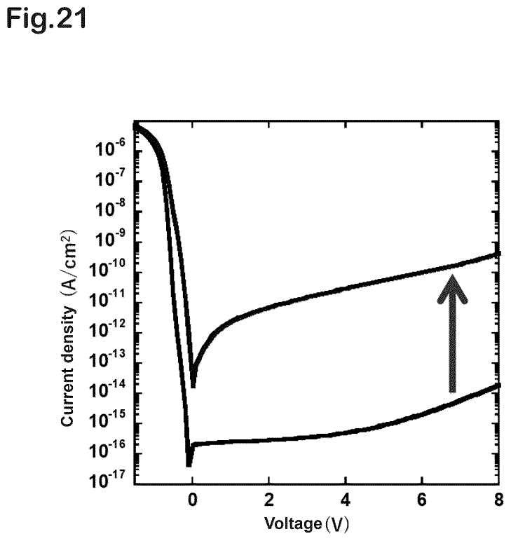

FIG. 21 shows results obtained by measuring I-V characteristics of the respective tunneling current driven elements according to Example and Comparative Example.

As shown in FIG. 21, it can be confirmed that the tunneling current driven element according to Example has an increase of the tunneling current of four orders of magnitude or more than the tunneling current driven element according to Comparative Example, and it is concluded that the tunneling current is increased through the formation of the quantum well layer.

Reference Signs List

| | |
|---|---|
| 1, 21, 31, 41 | first conductivity type semiconductor layer |
| 2, 22, 32, 42 | second conductivity type semiconductor layer |
| 3a, 23a, 33a, 43a | first base material layer |
| 3b, 23b, 33b, 43b | second base material layer |
| 4, 4′, 24, 34, 34′, 44 | quantum well layer |
| 10, 10′, 20, 30, 30′, 40 | tunneling current driven element |
| 25, 26 | metal electrode |
| 33 | base material layer |
| 35, 45 | source electrode |
| 36, 46 | drain electrode |
| 37, 47 | gate insulating film |
| 38, 48a | gate electrode |
| 48b | metal electrode |
| 100 | tunneling diode |
| 101 | N⁺ semiconductor layer |
| 102 | P⁺ semiconductor layer |
| 103 | intrinsic semiconductor layer |
| I | interlayer insulating film |
| S | support substrate |

1. A tunneling current driven element, comprising:
a first conductivity type semiconductor layer formed of an indirect transition semiconductor material, the first conductivity type semiconductor layer having a first conductivity type which is a conductivity type of at least one selected from the group consisting of a “p” type and an “n” type and having an impurity concentration of 3×10¹⁹ cm⁻³ or more;
a second conductivity type semiconductor layer formed of the indirect transition semiconductor material, the second conductivity type semiconductor layer having a second conductivity type which is a conductivity type different from the first conductivity type; and
an intermediate layer arranged so as to be sandwiched between the first conductivity type semiconductor layer and the second conductivity type semiconductor layer, the intermediate layer being formed of at least one selected from the group consisting of an intrinsic semiconductor and an impurity-containing semiconductor having an impurity concentration lower than impurity concentrations of the first conductivity type semiconductor layer and the second conductivity type semiconductor layer,
wherein the intermediate layer is a layer having a laminate structure in which, assuming a first direction directed from the first conductivity type semiconductor layer toward the second conductivity type semiconductor layer as a laminating direction, on the first conductivity type semiconductor layer serving as a base layer, at least one first base material layer and at least one quantum well layer are alternately laminated in the stated order, and a second base material layer is laminated on the at least one quantum well layer on a side closest to the second conductivity type semiconductor layer,
wherein the at least one first base material layer is a layer that is formed of a first semiconductor material selected from the indirect transition semiconductor material and has a thickness in the first direction of from 0.5 nm to 20 nm,
wherein the second base material layer is a layer that is formed of a second semiconductor material selected from the indirect transition semiconductor material and has a thickness in the first direction of from 10 nm to 500 nm, and
wherein the at least one quantum well layer is a layer that is formed of a third semiconductor material selected from the indirect transition semiconductor material of a type different from the first semiconductor material and the second semiconductor material and has a thickness in the first direction of from 0.5 nm to 10 nm, the third semiconductor material being selected from the indirect transition semiconductor material having a band structure of at least one selected from the group consisting of a first band structure and a second band structure, the first band structure having a valence band edge present at an energy position higher than valence band edges of the first semiconductor material and the second semiconductor material, the second band structure having a conduction band edge present at an energy position lower than conduction band edges of the first semiconductor material and the second semiconductor material.

2. The tunneling current driven element according to claim 1, wherein the band structure is at least one selected from the group consisting of a first band structure and a second band structure, the first band structure having the valence band edge present at an energy position higher by more than 0.1 eV than a valence band edge having a highest energy position out of the first semiconductor material and the second semiconductor material, the second band structure having the conduction band edge present at an energy position lower by more than 0.1 eV than a conduction band edge having a lowest energy position out of the first semiconductor material and the second semiconductor material.

3. The tunneling current driven element according to claim 1, wherein the first semiconductor material, the second semiconductor material and the third semiconductor material are at least one selected from the group consisting of the following combinations (1) to (6):
(1) a combination in which the first semiconductor material and the second semiconductor material are Si and the third semiconductor material is Si₁₋ₓGeₓ, where “x” exceeds 0 and is less than 1;
(2) a combination in which the first semiconductor material and the second semiconductor material are Si and the third semiconductor material is Ge;
(3) a combination in which the first semiconductor material and the second semiconductor material are Si₁₋ₓGeₓ, where “x” exceeds 0 and is less than 1, and the third semiconductor material is Si_{1-y}Ge_{y}, where “y” is a value exceeding 0 and being less than 1 and further being larger than “x”;
(4) a combination in which the first semiconductor material and the second semiconductor material are Si₁₋ₓGeₓ, where “x” exceeds 0 and is less than 1, and the third semiconductor material is Ge;
(5) a combination in which the first semiconductor material and the second semiconductor material are Si and the third semiconductor material is Si₁₋ₓCₓ, where “x” exceeds 0 and is less than 1; and
(6) a combination in which the first semiconductor material and the second semiconductor material are Si and the third semiconductor material is Si_{1-x-y}GeₓC_{y}, where “x” exceeds 0 and is less than 1, “y” exceeds 0 and is less than 1, and “x+y” is less than 1.

4. The tunneling current driven element according to claim 3, wherein the first semiconductor material, the second semiconductor material and the third semiconductor material are the combination (1), and “x” is 0.12 or more.

5. The tunneling current driven element according to claim 1, wherein the first conductivity type semiconductor layer, the second conductivity type semiconductor layer and the intermediate layer are each formed as a single crystal layer of the indirect transition semiconductor material.

6. The tunneling current driven element according to claim 1, wherein the thickness of the at least one first base material layer in the first direction is 8 nm or less.

7. The tunneling current driven element according to claim 1, further comprising an element structure of a tunneling diode in which, between an n-type semiconductor layer and a p-type semiconductor layer, a low impurity concentration layer is arranged, the low impurity concentration layer being formed of at least one selected from the group consisting of an intrinsic semiconductor and an impurity-containing semiconductor having an impurity concentration lower than impurity concentrations of the n-type semiconductor layer and the p-type semiconductor layer,
wherein the element structure includes at least one selected from the group consisting of a first element structure and a second element structure, the first element structure including: the n-type semiconductor layer formed of a first conductivity type semiconductor layer having a first conductivity type being an “n” type; the p-type semiconductor layer formed of a second conductivity type semiconductor layer having a second conductivity type being a “p” type; and the low impurity concentration layer formed of an intermediate layer, the second element structure including: the p-type semiconductor layer formed of the first conductivity type semiconductor layer having the first conductivity type being the “p” type; the n-type semiconductor layer formed of the second conductivity type semiconductor layer having the second conductivity type being the “n” type; and the low impurity concentration layer formed of the intermediate layer.

8. The tunneling current driven element according to claim 1, further comprising an element structure of a tunneling field effect transistor in which a channel region is formed between a source region and a drain region and a gate electrode is formed above the channel region through intermediation of a gate insulating film,
wherein the source region is formed of the first conductivity type semiconductor layer, the drain region is formed of the second conductivity type semiconductor layer, and the channel region is formed of the intermediate layer.

9. The tunneling current driven element according to claim 8, wherein a length of the at least one quantum well layer in a second direction orthogonal to the first direction as viewed from a position in contact with the gate insulating film is at least 5 nm.
